(19) United States
(12) Patent Application Publication
(10) Pub. No.: US 2025/0043217 A1
(43) Pub. Date: Feb. 6, 2025

(54) STRIPPER COMPOSITION AND METHOD FOR STRIPPING PHOTORESIST

(71) Applicant: Advanced Echem Materials Company Limited, Taoyuan (TW)

(72) Inventors: Chi-Liang He, Taoyuan (TW); Yun-Ju Chiang, Taoyuan (TW); Ting-Ruei Xu, Taoyuan (TW); Ming-Chia Tsai, Taoyuan (TW)

(73) Assignee: Advanced Echem Materials Company Limited, Taoyuan (TW)

(21) Appl. No.: 18/779,068

(22) Filed: Jul. 21, 2024

(30) Foreign Application Priority Data
Aug. 1, 2023 (TW) 112128761

(51) Int. Cl. C11D 7/50; C11D 7/06; C11D 7/26; C11D 7/32; G03F 7/42

(52) U.S. Cl. CPC C11D 7/5009; C11D 7/06; C11D 7/261; C11D 7/3209; C11D 7/3218; C11D 7/3281; C11D 7/5013; C11D 7/5022; G03F 7/425; G03F 7/426

(57) ABSTRACT

A stripper composition and a method for stripping a photoresist are provided. The stripper composition includes an ether-alcohol-based organic solvent (A), another organic solvent (B), an alkaline substance (C), a substrate corrosion inhibitor (D), and water (E). The another organic solvent (B) does not include the ether-alcohol-based organic solvent. The alkaline substance (C) includes an organic base (C1), an inorganic base (C2), or a combination thereof. Based on a total usage amount of 100 parts by weight of the stripper composition, a usage amount of the ether-alcohol-based organic solvent (A) is 7 parts by weight to 70 parts by weight, and a usage amount of the substrate corrosion inhibitor (D) is greater than 0 part by weight and less than 18 parts by weight.

### CROSS-REFERENCE TO RELATED APPLICATION

This application claims the priority benefit of Taiwan application no. 112128761, filed on Aug. 1, 2023. The entirety of the above-mentioned patent application is hereby incorporated by reference herein and made a part of this specification.

### BACKGROUND

### Technical Field

The disclosure relates to a stripper composition; more particularly, the disclosure relates to a stripper composition and a method for stripping photoresist.

### Description of Related Art

An existing stripper composition usually contains alkanolamine, which enables the removal of a photoresist from a substrate at elevated temperatures. However, while the photoresist is being stripped, the alkanolamine corrodes a film layer on the substrate that comes into contact with the photoresist. This situation impacts the functionality of a semiconductor device utilizing the substrate. As a result, there is an immediate requirement for an approach to address this phenomenon.

### SUMMARY

The disclosure provides a stripper composition that is characterized by good stripping abilities and is capable of resisting corrosions of an underlying contact surface during photoresist stripping and provides a method for stripping a photoresist.

A stripper composition of the disclosure includes an ether-alcohol-based organic solvent (A), another organic solvent (B), an alkaline substance (C), a substrate corrosion inhibitor (D), and water (E). The another organic solvent (B) does not include the ether-alcohol-based organic solvent. The alkaline substance (C) includes an organic base (C1), an inorganic base (C2), or a combination thereof. Based on a total usage amount of 100 parts by weight of the stripper composition, a usage amount of the ether-alcohol-based organic solvent (A) is 7 parts by weight to 70 parts by weight, and a usage amount of the substrate corrosion inhibitor (D) is greater than 0 part by weight and less than 18 parts by weight.

According to an embodiment of the disclosure, the ether-alcohol-based organic solvent (A) includes ethylene glycol monomethyl ether, ethylene glycol monoethyl ether, ethylene glycol monobutyl ether, propylene glycol monomethyl ether, propylene glycol monoethyl ether, propylene glycol monobutyl ether, diethylene glycol monomethyl ether, diethylene glycol monoethyl ether, diethylene glycol monobutyl ether, dipropylene glycol monomethyl ether, dipropylene glycol monoethyl ether, dipropylene glycol monobutyl ether, or a combination thereof.

According to an embodiment of the disclosure, the another organic solvent (B) includes 1,3-dimethyl-2-imidazolidinone, sulfolane, dimethy sulfoxide, propylene glycol monomethyl ether acetate, N-methyl-2-pyrrolidone, N-ethyl-2-pyrrolidone, N-butyl-2-pyrrolidone, dimethyl formamide, dimethyl acetamide, benzyl alcohol, butanol, butyrolactone, octanone, methy ethyl ketone, methyl benzoate, or a combination thereof.

According to an embodiment of the disclosure, the organic base (C1) includes tetramethyl ammonium hydroxide, tetraethyl ammonium hydroxide, or a combination thereof, and the inorganic base (C2) includes potassium hydroxide, sodium hydroxide, or a combination thereof.

According to an embodiment of the disclosure, the alkaline substance (C) includes the organic base (C1) and the inorganic base (C2).

According to an embodiment of the disclosure, the alkaline substance (C) includes the organic base (C1) and the inorganic base (C2), and based on the total usage amount of 100 parts by weight of the stripper composition, a usage amount of the organic base (C1) is 0.2 part by weight to 5 parts by weight, and a usage amount of the inorganic base (C2) is 0.5 part by weight to 3 parts by weight.

According to an embodiment of the disclosure, the substrate corrosion inhibitor (D) includes glycerol, ethylene glycol, polyvinylpyrrolidone, 2-mercaptobenzimidazole, polyethylene glycol, propylene glycol, or a combination thereof.

According to an embodiment of the disclosure, the substrate corrosion inhibitor (D) includes glycerol, and based on the total usage amount of 100 parts by weight of the stripper composition, a usage amount of the glycerol is greater than or equal to 1 part by weight and less than 4 parts by weight.

According to an embodiment of the disclosure, the stripper composition further includes alkanolamine (F), where based on the total usage amount of 100 parts by weight of the stripper composition, a usage amount of the alkanolamine (F) is 0 part by weight to 7 parts by weight.

According to an embodiment of the disclosure, the stripper composition further includes alkanolamine (F), and the alkanolamine (F) includes ethanolamine, triethanolamine, diethanolamine, isopropanolamine, or a combination thereof.

According to an embodiment of the disclosure, based on the total usage amount of 100 parts by weight of the stripper composition, a usage amount of the another organic solvent (B) is 10 parts by weight to 80 parts by weight, a usage amount of the alkaline substance (C) is 0.2 part by weight to 7.5 parts by weight, and a usage amount of the water (E) is 0.2 part by weight to 7.5 parts by weight.

In an embodiment of the disclosure, a method for stripping a photoresist is provided, and the method includes immersing a substrate containing the photoresist into the above-mentioned stripper composition.

In light of the foregoing, the stripper composition provided in one or more embodiments of the disclosure includes the ether-alcohol-based organic solvent (A), another organic solvent (B), the alkaline substance (C), the substrate corrosion inhibitor (D), and the water (E). Based on the total usage amount of the stripper composition being 100 parts by weight, the usage amount of the ether-alcohol-based organic solvent (A) is 7 parts by weight to 70 parts by weight, and the usage amount of the substrate corrosion inhibitor (D) is greater than 0 part by weight and less than 18 parts by weight. As such, the stripper composition may have a good stripping ability and may resist the corrosions of the underlying contact surface during photoresist stripping, so that the stripper composition is adapted to stripping the photoresist.

In order to make the aforementioned features and advantages of the disclosure more comprehensible, embodiments are described in detail below.

### DESCRIPTION OF THE EMBODIMENTS

### Stripper Composition

The disclosure provides a stripper composition including an ether-alcohol-based organic solvent (A), another organic solvent (B), an alkaline substance (C), a substrate corrosion inhibitor (D), and water (E). In addition, the stripper composition provided in the disclosure may further include alkanolamine (F) and other appropriate additives. These components will be elaborated hereinafter.

### Ether-Alcohol-Based Organic Solvent (A)

There is no specific restriction on the ether-alcohol-based organic solvent (A), and the appropriate ether-alcohol-based organic solvent (A) may be selected according to actual demands. In this embodiment, the ether-alcohol-based organic solvent (A) may include ethylene glycol monomethyl ether (EGME), ethylene glycol monoethyl ether (ECS), ethylene glycol monobutyl ether (BCS), propylene glycol monomethyl ether (PGME), propylene glycol monoethyl ether, propylene glycol monobutyl ether (PBBE), diethylene glycol monomethyl ether (DM), diethylene glycol monoethyl ether (DE), diethylene glycol monobutyl ether (DB), dipropylene glycol monomethyl ether (DPM), dipropylene glycol monoethyl ether, dipropylene glycol monobutyl ether (DPBM), a combination thereof, or another suitable ether-alcohol-based organic solvent. In an embodiment of the disclosure, the ether-alcohol-based organic solvent (A) is preferably DE, DB, PGME, or a combination thereof. The ether-alcohol-based organic solvent (A) may be used alone or in combination.

When the stripper composition includes the ether-alcohol-based organic solvent (A), the ether-alcohol-based organic solvent (A) is conducive to improvement of the ability of the stripper composition to resist corrosion of an underlying contact surface (e.g., a surface of a metal layer and/or a surface of a substrate) during photoresist stripping, thus enabling the stripper composition to have an improved ability to resist corrosion of the underlying contact surface during photoresist stripping.

Based on the total usage amount of 100 parts by weight of the stripper composition, the usage amount of the ether-alcohol-based organic solvent (A) is 7 parts by weight to 70 parts by weight; in an embodiment of the disclosure, the usage amount of the ether-alcohol-based organic solvent (A) is preferably 10 parts by weight to 68 parts by weight.

When the usage amount of the ether-alcohol-based organic solvent (A) in the stripper composition is within the above range, the ether-alcohol-based organic solvent (A) is conducive to improvement of the ability of the stripper composition to resist corrosion of the underlying contact surface (e.g., the surface of the substrate) during photoresist stripping, thus enabling the stripper composition to have an improved ability to resist corrosion of the underlying contact surface during photoresist stripping.

### Another Organic Solvent (B)

The another organic solvent (B) does not include the ether-alcohol-based organic solvent. In this embodiment, the another organic solvent (B) may include 1,3-dimethyl-2-imidazolidinone (DMI), sulfolane, dimethy sulfoxide (DMSO), propylene glycol monomethyl ether acetate (PGMEA), N-methyl-2-pyrrolidone (NMP), N-ethyl-2-pyrrolidone (NEP), N-butyl-2-pyrrolidone (MBP), dimethyl formamide (DMF), dimethyl acetamide (DMAC), benzyl alcohol (BA), butanol, butyrolactone, octanone, methy ethyl ketone (MEK), methyl benzoate, a combination thereof, or other suitable non-ether-alcohol-based organic solvents. In an embodiment of the disclosure, the another organic solvent (B) is preferably DMI, sulfolane, or a combination thereof. The another organic solvent (B) may be used alone or in combination.

Based on the total usage amount of 100 parts by weight of the stripper composition, the usage amount of the another organic solvent (B) is 10 parts by weight to 80 parts by weight; in an embodiment of the disclosure, the usage amount of the another organic solvent (B) is preferably 15 parts by weight to 76 parts by weight.

When the stripper composition includes the another organic solvent (B), the another organic solvent (B) is conducive to improvement of a swelling capacity of the stripper composition when the stripper composition is applied to remove the photoresist (the photoresist may swell due to the absorption of the another organic solvent (B), and therefore the photoresist may be stripped more easily) and solubility (the photoresist may be dissolved by the another organic solvent (B)); accordingly, the stripper composition has an improved photoresist stripping ability.

### Alkaline Substance (C)

The alkaline substance (C) includes an organic base (C1), an inorganic base (C2), or a combination thereof. The alkaline substance (C) may further include other suitable alkaline substances, and the alkaline substance (C) may be used alone or in combination.

There is no specific restriction on the organic base (C1), and the appropriate organic base may be selected according to actual demands. In this embodiment, the organic base (C1) may include tetramethyl ammonium hydroxide, tetraethyl ammonium hydroxide, a combination thereof, or other suitable organic bases. In an embodiment, the organic base (C1) is preferably tetraethyl ammonium hydroxide. The organic base (C1) may be used alone or in combination.

Based on the total usage amount of 100 parts by weight of the stripper composition, the usage amount of the organic base (C1) is 0.2 part by weight to 5 parts by weight. In an embodiment, the usage amount of the organic base (C1) is preferably 0.25 part by weight to 4 parts by weight.

There is no specific restriction on the inorganic base (C2), and the appropriate inorganic base may be selected according to actual demands. In this embodiment, the inorganic base (C2) may include potassium hydroxide (KOH), sodium hydroxide (NaOH), a combination thereof, or other suitable inorganic bases. In an embodiment of the disclosure, the inorganic base (C2) is preferably KOH. The inorganic base (C2) may be used alone or in combination.

Based on the total usage amount of 100 parts by weight of the stripper composition, the usage amount of the inorganic base (C2) is 0.5 part by weight to 3 parts by weight; in an embodiment, the usage amount of the inorganic base (C2) is preferably 1.25 parts by weight to 2.25 parts by weight.

When the stripper composition includes the alkaline substance (C), the alkaline substance (C) is conducive to breaking main chain bonds of large molecules in the photoresist, thus enabling the stripper composition to have an improved photoresist stripping ability.

In this embodiment, the alkaline substance (C) preferably includes the organic base (C1) and the inorganic base (C2). When the alkaline substance (C) in the stripper composition includes both the organic base (C1) and the inorganic base (C2), it is conducive to improvement of the stripping ability of the stripper composition, especially conducive to improvement of the stripping ability of the stripper composition for the photoresist with a relative large thickness (e.g., 100 μm to 350 μm), thus enabling the stripper composition to have an improved photoresist stripping ability when the stripper composition is applied to remove a relatively thick photoresist.

Based on the total usage amount of 100 parts by weight of the stripper composition, the usage amount of the alkaline substance (C) is 0.2 part by weight to 7.5 parts by weight; in an embodiment, the usage amount of the alkaline substance (C) is preferably 1 part by weight to 4 parts by weight.

### Substrate Corrosion Inhibitor (D)

There is no specific restriction on the substrate corrosion inhibitor (D), and the appropriate substrate corrosion inhibitor may be selected according to actual demands. In this embodiment, the substrate corrosion inhibitor (D) may include glycerol, ethylene glycol, polyvinylpyrrolidone, 2-mercaptobenzimidazole, polyethylene glycol, propylene glycol, a combination thereof, or other suitable substrate corrosion inhibitors. In an embodiment of the disclosure, the substrate corrosion inhibitor (D) is preferably glycerol, ethylene glycol, polyvinylpyrrolidone, 2-mercaptobenzimidazole, or a combination thereof. In another embodiment of the disclosure, the substrate corrosion inhibitor (D) is preferably glycerol. The substrate corrosion inhibitor (D) may be used alone or in combination.

When the stripper composition includes the substrate corrosion inhibitor (D), the substrate corrosion inhibitor (D) is conducive to improvement of a corrosion resistance of the stripper composition, thus enabling the stripper composition to have an improved corrosion resistance when the stripper composition is applied to remove a relatively thick photoresist (e.g., 100 μm to 350 μm). Besides, when the stripper composition includes the substrate corrosion inhibitor (D), the substrate corrosion inhibitor (D) is conducive to improvement of an ability of the stripper composition to resist corrosion of the underlying contact surface (e.g., the surface of the metal layer and the substrate) during photoresist stripping, thus enabling the stripper composition to have an improved ability to resist corrosion of the underlying contact surface during photoresist stripping.

In this embodiment, the substrate corrosion inhibitor (D) may include glycerol. Based on the total usage amount of 100 parts by weight of the stripper composition, the usage amount of glycerol is 1 part by weight to 12 parts by weight; in an embodiment of the disclosure, the usage amount of glycerol is preferably greater than or equal to 1 part by weight and less than 4 parts by weight. When the usage amount of glycerol included in the substrate corrosion inhibitor (D) in the stripper composition is within the above preferable range, the substrate corrosion inhibitor (D) may be conducive to improvement of a stripping ability of the stripper composition, especially conducive to the improvement of the stripping ability of the stripper composition for the photoresist with a thickness of 280 μm or more, thus enabling the stripper composition to have an improved stripping ability when the stripper composition is applied to remove the photoresist within a thickness of 280 μm or more.

Based on the total usage amount of 100 parts by weight of the stripper composition, the usage amount of the substrate corrosion inhibitor (D) is greater than 0 part by weight and less than 18 parts by weight; in an embodiment of the disclosure, the usage amount of the substrate corrosion inhibitor (D) is preferably 5 parts by weight to 17 parts by weight.

When the usage amount of the substrate corrosion inhibitor (D) in the stripper composition is within the above range, the substrate corrosion inhibitor (D) is conducive to improvement of the corrosion resistance of the stripper composition, thus enabling the stripper composition to have an improved corrosion resistance when the stripper composition is applied to remove a relatively thick photoresist.

### Water (E)

There is no specific restriction on water (E), and the appropriate water may be selected according to actual demands. For instance, the water (E) may include pure water, ultrapure water, deionized water, or any other appropriate water. In an embodiment of the disclosure, the water (E) is preferably ultrapure water.

Based on the total usage amount of 100 parts by weight of the stripper composition, the usage amount of the water (E) is 0.2 part by weight to 7.5 parts by weight; in an embodiment of the disclosure, the usage amount of the water (E) is preferably 0.4 part by weight to 7.5 parts by weight.

When the stripper composition includes the water (E), the water (E) is conducive to improvement of solubility of the stripper composition, thus enabling the stripper composition to have improved homogeneity.

### Alkanolamine (F)

There is no specific restriction on the alkanolamine (F), and the appropriate alkanolamine may be selected according to actual demands. In this embodiment, the alkanolamine (F) may include ethanolamine, triethanolamine, diethanolamine, isopropanolamine, a combination thereof, or other suitable alkanolamines. In an embodiment of the disclosure, the alkanolamine (F) is preferably ethanolamine, triethanolamine, or a combination thereof. The alkanolamine (F) may be used alone or in combination.

Based on the total usage amount of 100 parts by weight of the stripper composition, the usage amount of the alkanolamine (F) is 0 part by weight to 7 parts by weight; in an embodiment of the disclosure, the usage amount of the alkanolamine (F) is preferably 0 part by weight or 1 part by weight to 3 parts by weight.

When the stripper composition includes the alkanolamine (F), the alkanolamine (F) is conducive to improvement of solubility of residual photoresist, thus enabling the stripper composition to have improved solubility of the photoresist.

### Preparation Method of the Stripper Composition

There is no specific restriction on a preparation method of the stripper composition. For instance, the ether-alcohol-based organic solvent (A), the another organic solvent (B), the alkaline substance (C), the substrate corrosion inhibitor (D), and the water (E) were stirred in a stirrer and evenly mixed into a solution. If necessary, the alkanolamine (F) or other suitable additives may also be added. After the components were evenly mixed, a liquid stripper composition was obtained.

### Method for Stripping a Photoresist

An exemplary embodiment of the disclosure provides a method for stripping a photoresist, and the method includes immersing a substrate containing a photoresist into the stripper composition described above.

The substrate may be a glass substrate, a silicon wafer substrate, or any other suitable base material that is able to resist corrosion by alkaline substances.

The photoresist may be a positive photoresist or a negative photoresist. A material of the photoresist may include resin, a photosensitizer, and a solvent. The resin included in the positive photoresist may include phenolic resin or other suitable materials. The resin included in the negative photoresist may include acrylic resin or other suitable materials.

A metal layer may be formed on the topmost layer of one surface of the substrate. A material of the metal layer may include copper or other suitable metals.

Embodiments and examples are provided hereinafter to elaborate the invention, and the scope of the invention includes the claimed scope and substitutes and modifications thereof should not be limited to what is disclosed in the embodiments and the examples.

### EMBODIMENTS OF THE STRIPPER COMPOSITION

Embodiment 1 to Embodiment 11 and Comparative Example 1 to Comparative Example 5 of the stripper composition are described below.

### Embodiment 1

14 parts by weight of DE, 1.5 parts by weight of TEAH, 1.5 parts by weight of KOH, 1 part by weight of glycerol, 9 parts by weight of MEG, 0.5 part by weight of PVP, and 4.6 parts by weight of water were added to a mixed solvent composed of 30 parts by weight of DMI and 37.9 parts by weight of sulfolane. After the mixture is stirred evenly with a stirrer, the stripper composition provided in Embodiment 1 was obtained.

### Embodiment 2 to Embodiment 11 and Comparison Example 1 to Comparison Example 5

The stripper compositions provided in Embodiment 2 to Embodiment 11 and Comparison Example 1 to Comparison Example 5 were prepared by performing the same steps as in Example 1, while the differences therebetween lies in variations of the components and the usage amounts of the striper compositions (as shown in Table 1). The resultant striper compositions are evaluated in the following evaluation methods, and the evaluation results are shown in Table 2.

TABLE 1

| | No. | Component/Compound |
|---|---|---|
| Ether-alcohol- | A-1 | Diethylene glycol monoethyl ether (DE) |
| based organic | A-2 | Diethylene glycol monobutyl ether (DB) |
| solvent (A) | A-3 | Propylene glycol monomethyl ether (PGME) |
| Another organic | B-1 | 1,3-dimethyl-2-imidazolidinone (DMI) |
| solvent (B) | B-2 | Sulfolane |
| Alkaline | C-1 | Tetraethyl ammonium hydroxide (TEAH) |
| substance (C) | C-2 | Tetramethyl ammonium hydroxide (TMAH) |
| | C-3 | Potassium hydroxide KOH |
| Substrate | D-1 | Glycerol |
| corrosion | D-2 | Ethylene glycol (MEG) |
| inhibitor (D) | D-3 | Polyethylene glycol (PEG) |
| | D-4 | Propylene glycol (PG) |
| | D-5 | Polyvinylpyrrolidone (PVP) |
| | D-6 | 2-mercaptobenzimidazole (MBI) |
| Water (E) | E-1 | Ultrapure water |
| Alkanolamine (F) | F-1 | Ethanolamine (MEA) |
| | F-2 | Triethanolamine (TEA) |

TABLE 2

| Component | | Embodiment | | | | | | | |
|---|---|---|---|---|---|---|---|---|---|
| (unit: wt %) | | 1 | 2 | 3 | 4 | 5 | 6 | 7 | 8 |
| Ether-alcohol- | A-1 | 14 | 12 | 14 | 12 | 57.95 | 67.96 | 10 | — |
| based organic | A-2 | — | — | — | — | — | — | — | 20 |
| solvent (A) | A-3 | — | — | — | — | — | — | — | — |
| Another organic | B-1 | 30 | 30 | 30 | 30 | 20 | 10 | 30 | — |
| solvent (B) | B-2 | 37.9 | 40.54 | 36 | 38.4 | 5 | 5 | 45.4 | 61 |
| Alkaline | C-1 | 1.5 | 0.25 | 2 | 1.5 | 1.5 | 1.5 | 1 | 3.5 |
| substance (C) | C-2 | — | — | — | — | — | — | — | — |
| | C-3 | 1.5 | 2.25 | 1.25 | 1.8 | 2.25 | 2.25 | — | — |
| Substrate | D-1 | 1 | 1 | 1 | 1 | 1 | 1 | 4 | 8 |
| corrosion | D-2 | 9 | 11 | 9 | 11 | 9 | 9 | — | — |
| inhibitor (D) | D-3 | — | — | — | — | — | — | — | — |
| | D-4 | — | — | — | — | — | — | — | — |
| | D-5 | 0.5 | 0.5 | 1 | 0.5 | 0.5 | 0.5 | — | — |
| | D-6 | — | — | — | — | — | — | 1 | — |
| Water (E) | E-1 | 4.6 | 0.46 | 5.75 | 2.8 | 2.8 | 2.79 | 5.6 | 6.5 |
| Alkanolamine | F-1 | — | 2 | — | — | — | — | 3 | 1 |
| (F) | F-2 | — | — | — | 1 | — | — | — | — |
| Evaluation | Coopper Corrosion | ⊚ | ⊚ | ⊚ | ⊚ | ⊚ | ⊚ | ⊚ | ◯ |
| results | Resistance | | | | | | | | |
| | Silicon Corrosion | ⊚ | ⊚ | ⊚ | ⊚ | ⊚ | ⊚ | ⊚ | ⊚ |
| | Resistance | | | | | | | | |
| | PI Corrosion | ⊚ | ⊚ | ⊚ | ⊚ | ⊚ | ⊚ | ⊚ | ⊚ |
| | Resistance | | | | | | | | |
| | 120 μm-Photoresist | ⊚ | ⊚ | ⊚ | ⊚ | ⊚ | ⊚ | ⊚ | ⊚ |
| | Stripping Ability | | | | | | | | |
| | 280 μm-Photoresist | ⊚ | ⊚ | ⊚ | ⊚ | ⊚ | ⊚ | ◯ | ◯ |
| | Stripping Ability | | | | | | | | |
| Component | | Embodiment | | | Comparison Example | | | | |
| (unit: wt %) | | 9 | 10 | 11 | 1 | 2 | 3 | 4 | 5 |
| Ether-alcohol- | A-1 | — | — | — | — | 30 | 5 | — | — |
| based organic | A-2 | 10 | 30 | 30 | 13 | — | — | — | — |
| solvent (A) | A-3 | 10 | — | — | — | — | — | — | — |
| Another organic | B-1 | — | — | 30 | 17.8 | 30 | 15 | 47.63 | 82.51 |
| solvent (B) | B-2 | 55.6 | 48.57 | 18.7 | — | 16.1 | 62.71 | 33.37 | — |
| Alkaline | C-1 | 4 | 4 | — | 2 | — | 1.5 | 3.5 | 3.45 |
| substance (C) | C-2 | — | — | — | — | 2 | — | — | — |
| | C-3 | — | — | 1.5 | — | — | 1.5 | — | 0.72 |
| Substrate | D-1 | 12 | 10 | 6 | — | 6 | 1 | 4 | — |
| corrosion | D-2 | — | — | 10 | 48.5 | 10 | 9 | — | — |
| inhibitor (D) | D-3 | — | — | — | 15 | — | — | 2 | — |
| | D-4 | — | — | — | — | 1.01 | — | — | — |
| | D-5 | — | — | 1 | — | 1 | 0.5 | — | — |
| | D-6 | — | — | — | — | — | — | — | — |
| Water (E) | E-1 | 7.4 | 7.43 | 2.8 | 3.7 | 3.89 | 2.79 | 6.5 | 10.62 |
| Alkanolamine | F-1 | 1 | — | — | — | — | 1 | 3 | 2.7 |
| (F) | F-2 | — | — | — | — | — | — | — | — |
| Evaluation | Coopper Corrosion | ◯ | ⊚ | ⊚ | ⊚ | ⊚ | ⊚ | ⊚ | X |
| results | Resistance | | | | | | | | |
| | Silicon Corrosion | ⊚ | ⊚ | ⊚ | ⊚ | ⊚ | ⊚ | Δ | X |
| | Resistance | | | | | | | | |
| | PI Corrosion | ⊚ | ⊚ | ⊚ | ⊚ | ⊚ | X | X | X |
| | Resistance | | | | | | | | |
| | 120 μm-Photoresist | ⊚ | ⊚ | ◯ | X | X | ⊚ | ◯ | ⊚ |
| | Stripping Ability | | | | | | | | |
| | 280 μm-Photoresist | Δ | Δ | Δ | X | X | ◯ | X | ⊚ |
| | Stripping Ability | | | | | | | | |

### Evaluation Methods

a. Copper Corrosion Resistance

A substrate with a copper-plated surface was immersed in the stripper composition prepared in each embodiment and each comparison example for 70 minutes at a temperature of 70° C. Next, the copper-plated substrate that had been immersed was cleaned with deionized water and isopropanol. An etching rate of a copper-layer conductor on the substrate was then tested by applying a four-point probe principle. The four-point probe (model no.: LRS4-TG1, manufactured by KeithLink Technology Co., Ltd.) measurement method was performed by applying a fixed current between two of the probes; in the meantime, the voltage difference between the other two probes was measured, thereby calculating a sheet resistance. Next, by using a known formula, the change in the thickness of the copper layer was calculated to determine the copper corrosion rate, and accordingly the copper corrosion resistance is evaluated. The lower the copper corrosion rate is, the better the ability of the stripper composition to resist corrosion on the surface of the copper layer during photoresist stripping.

The evaluation criteria of the copper corrosion resistance are as follows:
⊚: the copper corrosion rate<0.2 Å/min;
◯: 0.2 Å/min≤the copper corrosion rate<2 Å/min;
Δ: 2 Å/min ≤ the copper corrosion rate<10 Å/min;
X: 10 Å/min ≤ the copper corrosion rate.
   b. Silicon Corrosion Resistance

A silicon substrate was immersed in the stripper composition prepared in each embodiment and each comparison example for 70 minutes at a temperature of 70° C. Next, the silicon substrate that had been immersed was cleaned with deionized water and isopropanol and was visually inspected to observe whether the silicon substrate was corroded in order to evaluate the silicon corrosion resistance thereof. The smaller the degree of corrosion/matting on the surface of the silicon substrate is, the greater the ability of the stripper composition to resist corrosion of the silicon substrate during photoresist stripping.

The evaluation criteria of the silicon corrosion resistance are as follows:
⊚: the silicon substrate is not corroded;
Δ: the surface of the silicon substrate is partially matted;
X: the surface of the silicon substrate is completely matted.
   c. PI Corrosion Resistance

A polyimide (PI)-plated substrate was immersed in the stripper composition prepared in each embodiment and each comparison example for 70 minutes at a temperature of 70° C. Next, the immersed PI-plated substrate was cleaned with deionized water and isopropanol. A thickness of the PI layer on the cleaned PI-plated substrate was measured by a film thickness meter (model no.: Dektak 8, manufactured by Veeco Instruments Inc.) to calculate the corrosion rate of the PI layer and accordingly evaluate the PI corrosion resistance. The lower the PI corrosion rate is, the better the ability of the stripper composition to resist corrosion of the PI layer during photoresist stripping.

The evaluation criteria of the PI corrosion resistance are as follows:
⊚: the PI corrosion rate<0.03 μm/min;
◯: 0.03 μm/min≤the PI corrosion rate<0.06 μm/min;
Δ: 0.06 μm/min≤the PI corrosion rate<0.14 μm/min;
X: 0.14 μm/min≤the PI corrosion rate ○
   d. Photoresist Stripping Ability

A substrate containing a photoresist (with a thickness of 120 μm and/or 280 μm and, for instance, a negative photoresist) was immersed in the stripper composition prepared in each embodiment and each comparison example for 70 minutes at a temperature of 70° C. Next, the substrate that had been immersed was cleaned with deionized water and isopropanol. The cleaned substrate was then observed by a metallographic microscope (model no: Nikon LV150N, manufactured by Nikon Corporation) to check for any photoresist residue on the substrate and accordingly evaluate the stripping ability. The higher the proportion of the photoresist stripped off from the substrate, the better the stripping ability of the stripper composition.

The evaluation criteria of the photoresist stripping ability are as follows:
⊚: the photoresist is completely stripped off from the substrate;
◯: 97%<the proportion of the photoresist being stripped off from the substrate<100%;
Δ: 90%<the proportion of the photoresist being stripped off from the substrate≤97%;
X: the proportion of the photoresist being stripped off from the substrate≤90%○

### Evaluation Results

As can be observed from Table 2, when the stripper composition includes the ether-alcohol-based organic solvent (A), the another organic solvent (B), the alkaline substance (C), the substrate corrosion inhibitor (D), and the water (E), and based on the total usage amount of 100 parts by weight of the stripper composition, when the usage amount of the ether-alcohol-based organic solvent (A) is 7 parts by weight to 70 parts by weight, the usage amount of the substrate corrosion inhibitor (D) is greater than 0 part by weight and less than 18 parts by weight (Embodiments 1-11), the stripper composition simultaneously has the good stripping ability and the ability to resist corrosion of the underlying contact surface during photoresist stripping, so that the stripper composition is adapted to photoresist stripping.

Besides, compared to the stripper composition (Comparative Examples 1-2) in which the usage amount of the substrate corrosion inhibitor (D) is not within the range of greater than 0 part by weight and less than 18 parts by weight, the stripper composition (Embodiments 1-11) in which the usage amount of the substrate corrosion inhibitor (D) is within the range of greater than 0 part by weight and less than 18 parts by weight has the improved stripping ability. Accordingly, when the usage amount of the substrate corrosion inhibitor (D) is greater than 0 part by weight and less than 18 parts by weight, the substrate corrosion inhibitor (D) within a specific usage range is able to improve the proportion of the photoresist being stripped off from the substrate by applying the stripper composition, thus enabling the stripper composition to have the improved stripping ability. Meanwhile, the stripper composition has the good ability to effectively resist corrosion of the underlying contact surface during photoresist stripping.

Compared to the stripper composition (Comparative Example 3) in which the usage amount of the ether-alcohol-based organic solvent (A) is not within the range of 7 parts by weight to 70 parts by weight, the stripper composition (Embodiments 1-11) in which the usage amount of the ether-alcohol-based organic solvent (A) is within the range of 7 parts by weight to 70 parts by weight has the improved PI corrosion resistance. Accordingly, when the usage amount of the ether-alcohol-based organic solvent (A) is 7 parts by weight to 70 parts by weight, the ether-alcohol-based organic solvent (A) within a specific usage range is able to improve the ability of the stripper composition to resist corrosion of the PI layer during photoresist stripping, thus enabling the stripper composition to have the improved ability to effectively resist corrosion of the underlying contact surface during photoresist stripping and meanwhile have the improved stripping ability.

In addition, compared to the stripper composition (Comparative Examples 4-5) which does not include the ether-alcohol-based organic solvent (A), the stripper composition (Embodiments 1-11) which includes the ether-alcohol-based organic solvent (A) has the improved copper corrosion resistance, the improved silicon corrosion resistance, and/or the improved PI corrosion resistance. Accordingly, when the stripper composition includes the ether-alcohol-based organic solvent (A), the ether-alcohol-based organic solvent (A) is able to improve the ability of the stripper composition to resist corrosion of the copper layer, the PI layer, and/or the surface of the silicon substrate during photoresist stripping, thus enabling the stripper composition to have the improved ability to resist corrosion of the underlying contact surface during photoresist stripping and meanwhile have the improved stripping ability.

Moreover, compared to the stripper composition (Comparative Example 5) which does not include the substrate corrosion inhibitor (D), the stripper composition (Embodiments 1-11) which includes the substrate corrosion inhibitor (D) has the improved copper corrosion resistance, the improved silicon corrosion resistance, and the improved PI corrosion resistance. Accordingly, when the stripper composition includes the substrate corrosion inhibitor (D), the substrate corrosion inhibitor (D) is able to improve the corrosion resistance of the stripper composition, thus enabling the stripper composition to have the improved corrosion resistance during photoresist stripping and meanwhile have the improved stripping ability.

Additionally, compared to the stripper composition (Embodiments 7-11) in which the alkaline substance (C) does not include a combination of the organic base (C1) and the inorganic base (C2), the stripper composition (Embodiments 1-6) in which the alkaline substance (C) includes a combination of the organic base (C1) and the inorganic base (C2) has the improved 280 μm-photoresist stripping ability. Accordingly, when the alkaline substance (C) in the stripper composition includes a combination of the organic base (C1) and the inorganic base (C2), the alkaline substance (C) is able to improve the proportion of the photoresist being stripped off from the substrate by the stripper composition, especially in improving the stripping ability of the stripper composition to remove a relatively thick photoresist (e.g., 100 μm to 350 μm), thus enabling the stripper composition to have the improved stripping ability and meanwhile have the improved ability to effectively resist corrosion of the underlying contact surface during photoresist stripping.

In addition, compared to the stripper composition (Embodiments 7-11) in which the substrate corrosion inhibitor (D) includes the glycerol, while the usage amount of the glycerol is not within the range of greater than or equal to 1 part by weight and less than 4 parts by weight, the stripper composition (Embodiments 1-6) in which the substrate corrosion inhibitor (D) includes the glycerol and the usage amount of the glycerol is within the range of greater than or equal to 1 part by weight and less than 4 parts by weight has the improved 280 μm-photoresist stripping ability. Accordingly, when the substrate corrosion inhibitor (D) in the stripper composition includes the glycerol, and the usage amount of the glycerol is greater than or equal to 1 part by weight and less than 4 parts by weight, the substrate corrosion inhibitor (D) is able to improve the proportion of the photoresist being stripped off from the substrate by the stripper composition, especially in improving the stripping ability of the stripper composition to remove a relatively thick photoresist (e.g., 100 μm to 350 μm), thus enabling the stripper composition to have the improved stripping ability and meanwhile the improved ability to resist corrosion of the underlying contact surface during photoresist stripping.

To sum up, the stripper composition provided in one or more embodiments of the disclosure includes the ether-alcohol-based organic solvent (A), another organic solvent (B), the alkaline substance (C), the substrate corrosion inhibitor (D), and the water (E). Based on the total usage amount of the stripper composition being 100 parts by weight, the usage amount of the ether-alcohol-based organic solvent (A) is 7 parts by weight to 70 parts by weight, and the usage amount of the substrate corrosion inhibitor (D) is greater than 0 part by weight and less than 18 parts by weight. As such, the stripper composition may have a good stripping ability and may resist the corrosions of the underlying contact surface during photoresist stripping, so that the stripper composition is adapted to stripping the photoresist. Moreover, the stripper composition provided herein is adapted to manufacturing a semiconductor device and may improve the performance of the semiconductor device utilizing the stripper composition.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A stripper composition, comprising:
an ether-alcohol-based organic solvent (A);
another organic solvent (B), wherein the another organic solvent (B) does not comprise the ether-alcohol-based organic solvent;
an alkaline substance (C), comprising an organic base (C1), an inorganic base (C2), or a combination thereof;
a substrate corrosion inhibitor (D); and
water (E),
wherein based on a total usage amount of 100 parts by weight of the stripper composition, a usage amount of the ether-alcohol-based organic solvent (A) is 7 parts by weight to 70 parts by weight, and a usage amount of the substrate corrosion inhibitor (D) is greater than 0 part by weight and less than 18 parts by weight.

2. The stripper composition according to claim 1, wherein the ether-alcohol-based organic solvent (A) comprises ethylene glycol monomethyl ether, ethylene glycol monoethyl ether, ethylene glycol monobutyl ether, propylene glycol monomethyl ether, propylene glycol monoethyl ether, propylene glycol monobutyl ether, diethylene glycol monomethyl ether, diethylene glycol monoethyl ether, diethylene glycol monobutyl ether, dipropylene glycol monomethyl ether, dipropylene glycol monoethyl ether, dipropylene glycol monobutyl ether, or a combination thereof.

3. The stripper composition according to claim 1, wherein the another organic solvent (B) comprises 1,3-dimethyl-2-imidazolidinone, sulfolane, dimethy sulfoxide, propylene glycol monomethyl ether acetate, N-methyl-2-pyrrolidone, N-ethyl-2-pyrrolidone, N-butyl-2-pyrrolidone, dimethyl formamide, dimethyl acetamide, benzyl alcohol, butanol, butyrolactone, octanone, methy ethyl ketone, methyl benzoate, or a combination thereof.

4. The stripper composition according to claim 1, wherein the organic base (C1) comprises tetramethyl ammonium hydroxide, tetraethyl ammonium hydroxide, or a combination thereof, and the inorganic base (C2) comprises potassium hydroxide, sodium hydroxide, or a combination thereof.

5. The stripper composition according to claim 1, wherein the alkaline substance (C) comprises the organic base (C1) and the inorganic base (C2).

6. The stripper composition according to claim 1, wherein the alkaline substance (C) comprises the organic base (C1) and the inorganic base (C2), and based on the total usage amount of 100 parts by weight of the stripper composition, a usage amount of the organic base (C1) is 0.2 part by weight to 5 parts by weight, and a usage amount of the inorganic base (C2) is 0.5 part by weight to 3 parts by weight.

7. The stripper composition according to claim 1, wherein the substrate corrosion inhibitor (D) comprises glycerol, ethylene glycol, polyvinylpyrrolidone, 2-mercaptobenzimidazole, polyethylene glycol, propylene glycol, or a combination thereof.

8. The stripper composition according to claim 1, wherein the substrate corrosion inhibitor (D) comprises glycerol, and based on the total usage amount of 100 parts by weight of the stripper composition, a usage amount of the glycerol is greater than or equal to 1 part by weight and less than 4 parts by weight.

9. The stripper composition according to claim 1, further comprising alkanolamine (F), wherein based on the total usage amount of 100 parts by weight of the stripper composition, a usage amount of the alkanolamine (F) is 0 part by weight to 7 parts by weight.

10. The stripper composition according to claim 1, further comprising alkanolamine (F), wherein the alkanolamine (F) comprises ethanolamine, triethanolamine, diethanolamine, isopropanolamine, or a combination thereof.

11. The stripper composition according to claim 1, wherein based on the total usage amount of 100 parts by weight of the stripper composition, a usage amount of the another organic solvent (B) is 10 parts by weight to 80 parts by weight, a usage amount of the alkaline substance (C) is 0.2 part by weight to 7.5 parts by weight, and a usage amount of the water (E) is 0.2 part by weight to 7.5 parts by weight.

12. A method for stripping a photoresist, comprising:
immersing a substrate containing the photoresist into the stripper composition according to claim 1.
